(19) United States
(12) Patent Application Publication
(10) Pub. No.: US 2025/0071923 A1
(43) Pub. Date: Feb. 27, 2025

(54) CARD EDGE CONNECTOR WITH AN IMPROVED RELEASING MEMBER

(71) Applicants: FOXCONN (KUNSHAN) COMPUTER CONNECTOR CO., LTD., Kunshan (CN); FOXCONN INTERCONNECT TECHNOLOGY LIMITED, Grand Cayman (KY)

(72) Inventors: KUO-CHUN HSU, New Taipei (TW); Ming-Yi Gong, Huaian (CN); Yu-Che Huang, New Taipei (TW); Wen-Lung Hsu, New Taipei (TW); Po-Fu Chen, New Taipei (TW); Xun Wu, Huaian (CN); Wen-Ting Yu, New Taipei (TW); Chin-Chuan Wu, New Taipei (TW); Wei-Chia Liao, New Taipei (TW)

(21) Appl. No.: 18/808,375

(22) Filed: Aug. 19, 2024

(30) Foreign Application Priority Data
Aug. 21, 2023 (CN) 202311054651.4

(51) Int. Cl. H05K 7/14; G06F 1/18

(52) U.S. Cl. CPC H05K 7/1402; G06F 1/183

(57) ABSTRACT

A card edge connector includes: a connector base having a card slot and plural terminals; a latch located at one end of the connector base for locking a card; and a releasing member. The releasing member includes two levers and a moving member, the levers are connected with the connector base in a pivoting manner, a first end of the lever is connected with the latch and an opposite second end of the lever is coupled to the moving member, wherein when the card is inserted into the slot and presses against the moving member downwards, the moving member drives the second ends of the levers to move downward, resulting in the first ends moving upwards to push the latch to lock with the card, and when the card is pulled out the moving member resets and drives the levers to release the latch from the card.

### BACKGROUND OF THE INVENTION

### 1. Field of the Invention

The present invention relates to a card edge connector with a card latch.

### 2. Description of Related Art

Mother boards on computers, servers and other devices have multiple electrical connectors for expanding functions, such as AGP connector, PCI connector and USB connector. Electronic cards, such as display card or network card, are inserted into various connectors on the mother board and locked by latches of the connectors to expand the function of the computer. It may be difficult for users to release the latch by hand or through a tool. China Patent No. 102082339B discloses a connecting member extending from the latch, and the user pulls the connecting member to release the locking relationship between the latch and the card. U.S. Pat. No. 11,868,187 discloses a transmission mechanism added beside the connector. The user presses the transmission mechanism to transmit the force to rotate the latch outwards and release the locking engagement of the latch. It requires an user to exert force on the card while acting on the connecting member or the transmission mechanism, i.e., releasing the latch firstly and then pulling out the electronic card.

Therefore, an improved card edge connector is desired.

### SUMMARY OF THE INVENTION

The instant invention is to provide an electrical connector with an improved releasing member.

To achieve the above-mentioned object, a card edge connector adapted for an insertion of an electronic card comprises: a connector base having a card slot and plural terminals located at opposite sides of the card slot; a latch located at one end of the connector base for locking the electronic card inserted into the card slot; and a releasing member; wherein the releasing member comprises two levers and a moving member, the levers are disposed at outsides of the card slot and are connected with the connector base in a pivoting manner, a first end of the lever is connected with the latch and an opposite second end of the lever is connected with the moving member; and wherein when the electronic card is inserted into the card slot and presses against the moving member downwards, the moving member drives the second ends of the levers to move downward, resulting in the first ends of the lever moving upwards to push the latch to lock with the electronic card, and when the electronic card is pulled out the moving member resets and drives the levers to release the latch from the electronic card.

Other advantages and novel features of the invention will become more apparent from the following detailed description of the present embodiment when taken in conjunction with the accompanying drawings.

### BRIEF DESCRIPTION OF THE DRAWINGS

FIG. 1 is a perspective view of a card edge connector of the present invention;

FIG. 2 is a cross sectional view of the card edge connector taken along line A-A in FIG. 1;

FIG. 3 is a cross-sectional view similar to FIG. 2 showing the card edge connector being inserted with the electronic card;

FIG. 4 is a cross sectional view of the card edge connector taken along line B-B in FIG. 1;

FIG. 5 is an exploded perspective view of the card edge connector in FIG. 1;

FIG. 6 is another perspective view of card edge connector without a metallic shell in FIG. 5;

FIG. 7 is a front view of the card edge connector in FIG. 5, wherein a releasing member is in a free state without an insertion of the electronic card;

FIG. 8 is a front view similar to FIG. 7 showing the releasing member is in a locking state with the insertion of the electronic card;

FIG. 9 is a perspective view of the releasing member and the latch in FIG. 5;

FIG. 10 is an exploded perspective view of the releasing member and the latch in FIG. 9;

FIG. 11 is a further exploded perspective view of the card edge connector without the releasing member and the latch in FIG. 6; and

FIG. 12 is another exploded perspective view of the card edge connector in FIG. 11.

### DETAILED DESCRIPTION OF THE PREFERRED EMBODIMENT

Reference will now be made in detail to the preferred embodiment of the present invention.

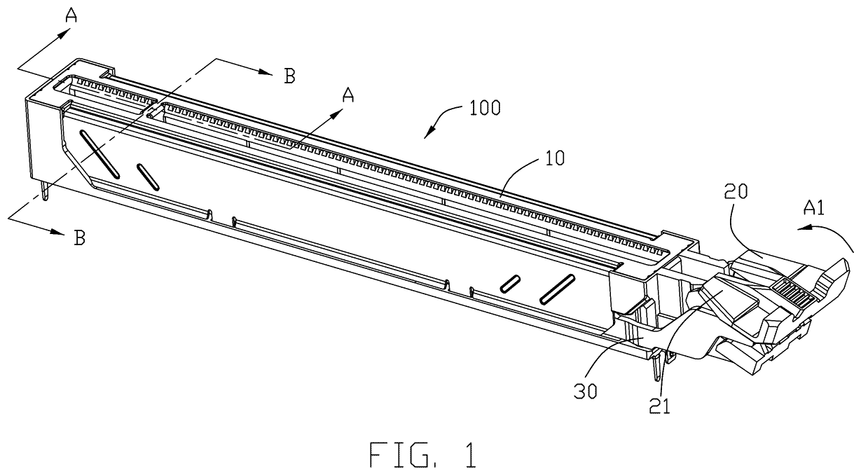

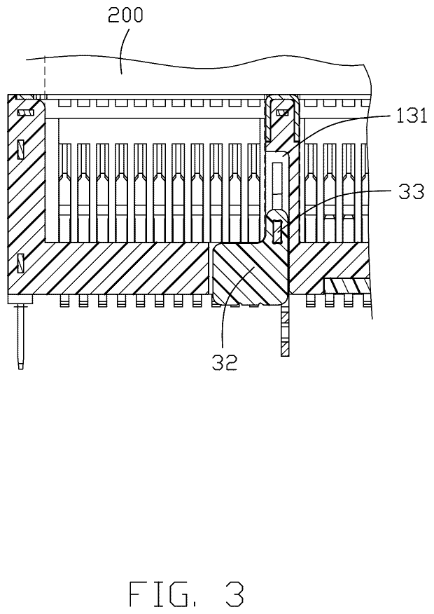

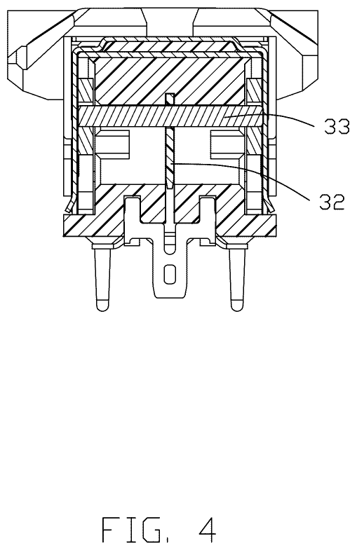

A card edge connector 100 of this embodiment is adapted for an insertion of an electronic card 200 in a diagrammatic sketch shown in FIG. 3, such as PCI Express card, to obtain an electronic connection between the electronic card 200 and a printed circuit board where the connector is mounted. Referring to FIGS. 1-5, the card edge connector 100 includes a connector base 10 and a latch 20 located at a longitudinal end of the connector base 10. The connector base 10 has a card slot 11 and plural terminals 12 disposed at opposite sides of the card slot 11. The latch 20 is used to lock the inserted card in the connector base 10, to avoid a release of the card from the connector base 10. The latch 20 is assembled at one longitudinal end of the connector base 10 or alternatively located near the connector base 10.

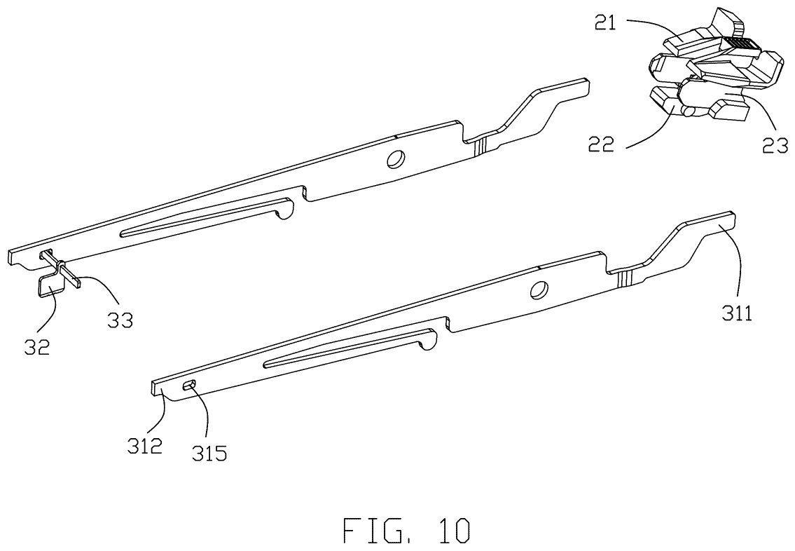

The latch 20 rotates towards the connector base 10 as Arrow A1 shown in FIG. 1, a locking portion 21 of the latch is bucked in a notch defined on one end of the card. When the latch 20 is pushed to rotate outwards apart from the connector base 10, an ejecting portion 22 of the latch as shown in FIG. 10 ejects upwards to push the card to move upwards, driving the card disconnect from the connector base 10. The improvement of this present invention is that a release member 30 is added to the connector base 10. The release member 30 is pushed downwards to store energy when the card is inserted into the slot 11 and simultaneously push the release member 30 to move downwards. When the user is ready to pull out the card from the connector base 10, it is not necessary to open the latch 20 firstly, the user can lightly pull out the card to release the energy stored by the releasing member 30 when the electronic card is inserted. The released energy drives the latch 20 to rotate outward to be opened in an opening state. In this embodiment, when the electronic card is inserted, the releasing member 30 has an elastic deformation so as to store energy, and when the card is removed by the user, the energy is released through the lever of the releasing member, so as to realize the propping effect.

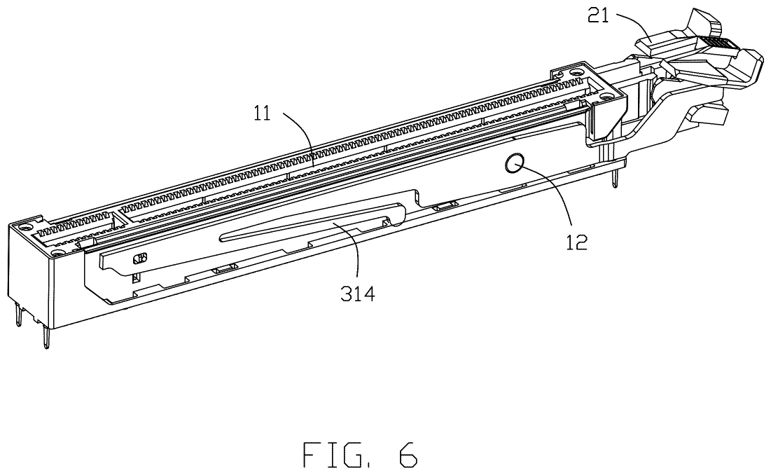

Referring to FIGS. 6 and 9-10, in this embodiment, the releasing member 30 includes two levers 31 and a moving member 32. Two levers 31 are disposed at outsides of the slot 11 and are pivotally connected to the connector base 10 as best shown in FIG. 6. A first end 311 of the lever 31 is connected to the latch 20, and the opposite second end 312 is connected to the moving member 32. Each lever 31 is formed by punching from a metal plate, and is vertically attached to the side of the connector base 10. Each side of the connector base 10 has a pivoting shaft 12, and the lever 31 has a pivoting hole 313 to match with the pivoting shaft 12 so that the lever 31 is connected to the connector base 10 in a pivoting connection. The two sides of the latch 20 have grooves 23, the first ends 311 of the levers are respectively contained in the grooves 23. A spring portion 314 integrally extends from the second end 312 of the lever 31, and a distal end 3141 of the spring portion 314 is supported to form a pre-pressure force to urge the moving member 31 to reset. In this embodiment, the spring portion 314 is of an arm-like structure or a spring arm which extends obliquely downward from the second end 312 of the lever 30, and the distal end 3141 is supported on the connector base 10. Alternatively, the distal end 3141 may also be supported on the circuit board through the connector base 10.

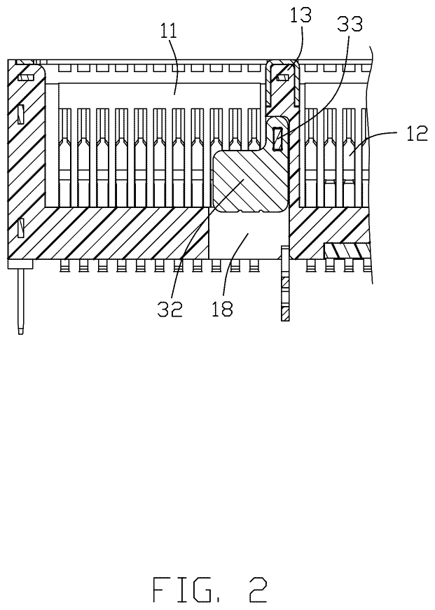

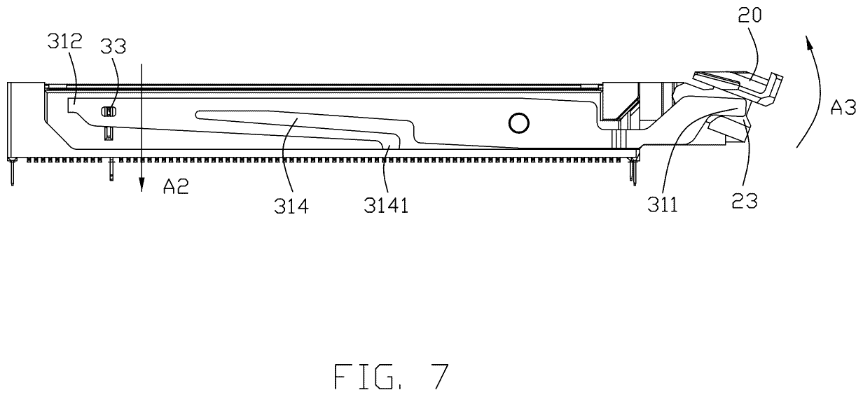

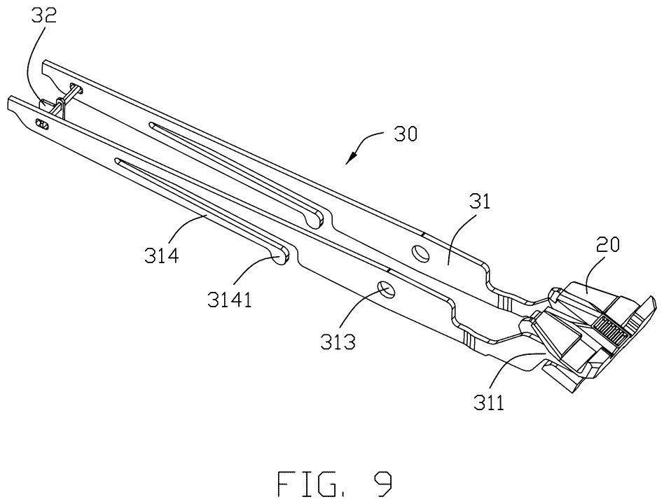

Referring to FIGS. 9-10, in this embodiment, the moving member 32 is of an L-shaped upright sheet, which is arranged in an upright direction. The structure of L-shaped upright sheet makes the moving member 32 avoid contacting the terminals 20, as shown in FIG. 2. The moving member 32 is connected to the second end 312 of the lever by a cross bar 33, and the connector base 10 has a receiving slot 18 going through from a bottom of the card slot 11 to a bottom of the connector base 10. The cross bar 33 moves downwards and then is received in the receiving slot 18 so that the moving member 32 moves downward without interfering with the inserted card 200. When in a free state that the card is not inserted into the connector base, the moving member 32 is located in the card slot 11, while the moving member 32 moves into the receiving slot 18 when in an inserted state that the card is inserted into the connector base 10. The second end 312 of the lever 31 has a hole 315, the upper end of the moving member 32 has a hole (not labeled), and the cross bar 33 passes through the hole of the moving member 32 and the hole 315 on the second end 312 of the lever, so as to form a linkage structure. When the moving member 32 is urged to move downwards as shown in arrow A2 in FIG. 7, the moving member 32 drives the latch 20 to rotate upward or towards the connector base 10 as shown in arrow A3 in FIG. 7 through the lever 30. Alternatively, the moving member 32 can be connected to the lever by other structures, such as a U-shaped metal member buried in the side walls at the two opposite sides of the card slot 11.

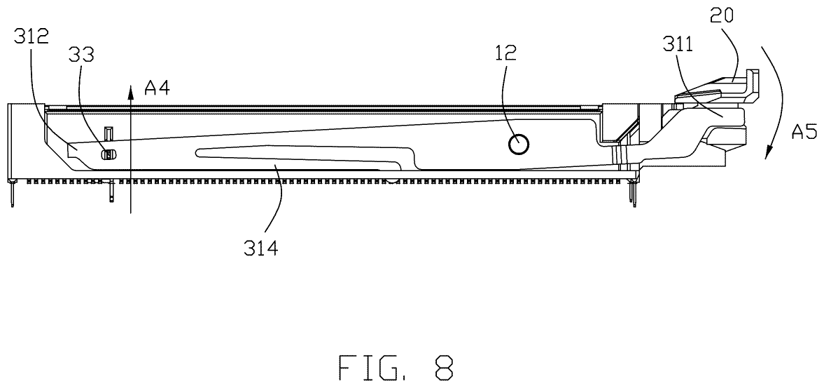

When the electronic card is inserted downward into the card slot 11, the lower edge of the electronic card drives the moving member 32 to move downwards, resulting that the second ends 312 of the levers moves downwards while the first ends 311 of the lever move upwards around the pivot shafts 13. The first ends 311 drive the latch 20 to rotate inwards or towards the connector base 10, so as to realize the lock engagement. During the downward movement of the second ends 312 of the levers, the distal ends 3141 of the spring portions 314 are stopped by the connector base 10 and cannot move, so that the spring portions 314 wholly move downward and generate elastic deformation so as to store energy, as shown in FIG. 8. When the electronic card is ready to be pulled out, there is no need to open the latch 20 firstly. The user slightly pulls the electronic card upwards, the limitation on the moving member 32 is released, the energy stored by the spring portion 314 is released, the spring portion 314 causes the upward movement the second ends 312 of the levers as shown in arrow A4 in FIG. 8. Meanwhile, the first ends 311 of the levers 30 move downwardly about the pivot shafts 12 in arrow A5 as shown in FIG. 8, to drive the latch 20 to move outwardly, so that the latch 20 is released from the electronic card.

In this embodiment, the lever 31 of the releasing member 30 is vertically disposed at both sides of the connector base 10, and the space of the connector base 10 is fully utilized. The connector base 10 has a key 13 across the card slot 11, the key 13 has a slit 131 to receive the cross bar 33. The cross bar 33 moves up and down in the slit 131. The position of the cross bar 33 in the key 13 fully utilizes the connector base and will not increase the length of the connector base 10. In this embodiment, there are two levers 31, which are respectively set at the two outsides of the connector base 10 to balance the posture of the latch 20 when being opened.

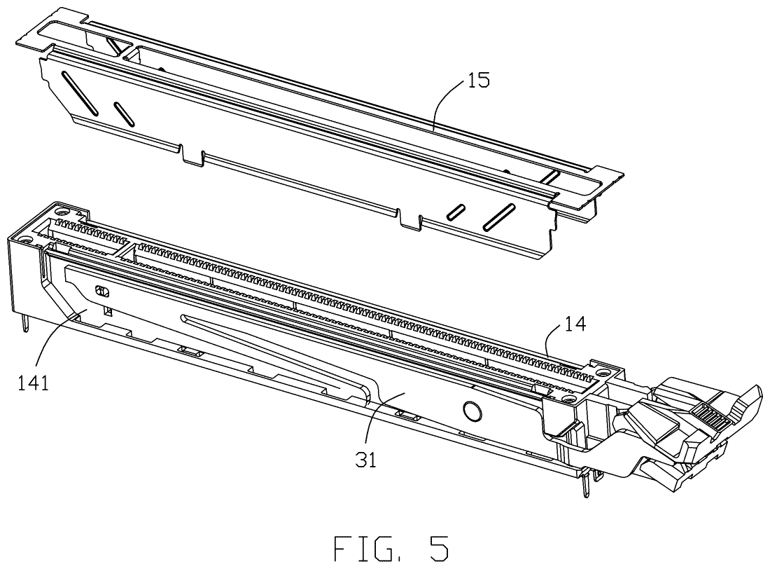

Referring to FIG. 5 and FIG. 6, the connector base 10 comprises a longitudinal insulating housing 14 and two rows of conductive terminals 12. The insulating housing 14 has the longitudinal card slot 11 and recessed portions 141 at the two outsides of the card slot. The lever 31 is attached in the recessed portions 141. The spring portion 314 is located close to the second end 312 and pressed against the bottom of the recessed portions 141. The metallic shell 15 fitly surrounds the outside of the insulating housing 10, two side plates of the metallic shell are adhered to the two outsides of the insulating housing, so as to limit the lever 31 in the recessed portions. The metallic shell 15 not only has a shielding function, but also can make the whole connector neat.

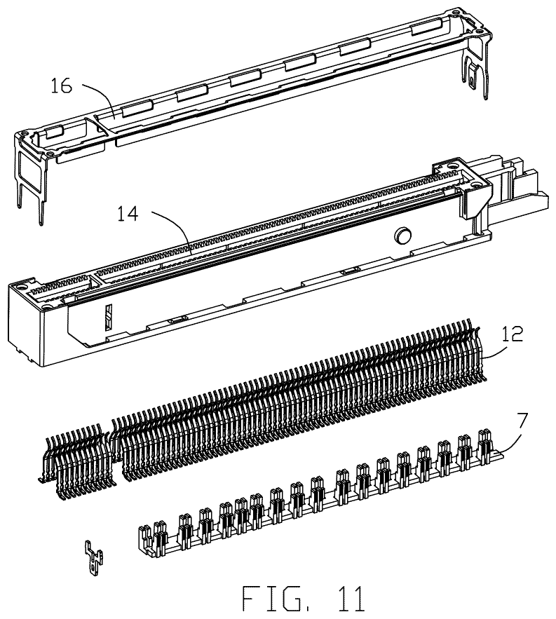

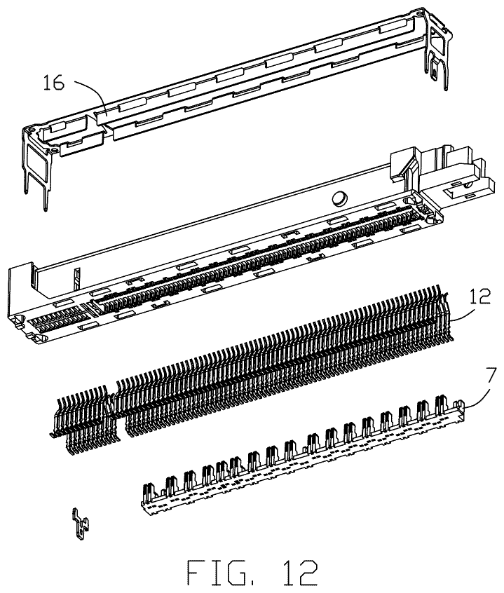

Referring to FIGS. 11 and 12, an inner shield 16 is embedded in the two longitudinal side walls of the insulating housing 14, and a filling member 17 is inserted in the insulating housing and fills the terminal passageways receiving the signal terminals so that the dielectric constant of the signal terminal is improved.

Although the present invention has been described with reference to particular embodiments, it is not to be construed as being limited thereto. Various alterations and modifications can be made to the embodiments without in any way departing from the scope or spirit of the present invention as defined in the appended claims.

1. A card edge connector adapted for an insertion of an electronic card, comprising:
a connector base having a card slot and plural terminals located at opposite sides of the card slot;
a latch located at one end of the connector base for locking the electronic card inserted into the card slot; and
a releasing member;
wherein the releasing member comprises two levers and a moving member, the levers are disposed at outsides of the card slot and are connected with the connector base in a pivoting manner, a first end of the lever is connected with the latch and an opposite second end of the lever is coupled to the moving member;
wherein when the electronic card is inserted into the card slot and presses against the moving member downwards, the moving member drives the second ends of the levers to move downward, resulting in the first ends of the lever moving upwards to push the latch to lock with the electronic card, and when the electronic card is pulled out the moving member resets and drives the levers to release the latch from the electronic card.

2. The card edge connector as claimed in claim 1, wherein the lever is made of a metal plate, the levers are deformed to store energy when the electronic card is inserted into the card slot, and the levers release the stored energy to reset the moving member and the levers when the electronic card is pulled out.

3. The card edge connector as claimed in claim 1, wherein the lever is made of a metal plate, a spring portion unitarily extends from the metal plate, and the spring portion is able to be deformed to reset the moving member.

4. The card edge connector as claimed in claim 3, wherein the spring portion obliquely extends downwards from the second end of the lever, and a distal end of the spring portion is supported on the connector base or on a printed circuit board where the connector base is mounted.

5. The card edge connector as claimed in claim 1, wherein the moving member is of an upright sheet and is received in the card slot, and the moving member is able to move into a receiving slot defined under the card slot when the moving member is pushed downwards.

6. The card edge connector as claimed in claim 1, wherein the second ends of the levers are transversely connected together by a cross bar, and the moving member is connected with the cross bar to form a linkage structure.

7. The card edge connector as claimed in claim 6, wherein the connector base has a key crossing the card slot, the key has a slit, and the cross bar is received in the slit.

8. The card edge connector as claimed in claim 1, wherein the connector base comprises a longitudinal insulating housing and the terminals, the insulating housing body has the card slot and two recessed portions at outsides thereof, and the levers are attached in the recessed portions respectively.

9. The card edge connector as claimed in claim 8, wherein the insulating housing has a pivot shaft at each of the recessed portions, and the lever has a respective pivot hole to engage with each pivot shaft.

10. The card edge connector as claimed in claim 9, wherein a spring arm extends slantwise and downward from the second end of the lever toward the pivot hole.

11. The card edge connector as claimed in claim 10, wherein the connector base comprises a metallic shell surrounding the insulating housing and hiding the levers therein.

12. A card edge connector comprising:
a longitudinal connector base having two longitudinal walls, a card slot between the two longitudinal walls, a pivoting shaft protruding outward from each of the longitudinal walls and proximate to a first end of the connector base, and plural terminals located at opposite sides of the card slot;
a latch being located at the first end of the connector base and pivotable towards or away from the card slot; and
a releasing member;
wherein the releasing member comprises two levers and a moving member, the levers are attached to the longitudinal walls and each lever has a pivoting hole assembled with the pivoting shaft of the connector base, the moving member is received in the card slot, first ends of the levers are connected with the latch and opposite second ends of the levers are coupled to the moving member, a spring portion extends slantwise from the lever downward toward the pivoting hole, and the spring portion presses against a lower portion of the connector base or a printed circuit board where the connector base is mounted.

13. The card edge connector as claimed in claim 12, wherein a cross bar is lateral connected with the two second ends of the levers, and the moving member is uprightly connected with the cross bar.

14. The card edge connector as claimed in claim 12, wherein a key is laterally located in the card slot, the cross bar is located in a slit defined in the key.

15. The card edge connector as claimed in claim 12, wherein a metallic shell surrounds the connector base and covers the levers therein.

16. A card edge connector adapted for an insertion of an electronic card, comprising:
a connector base having a card slot and plural terminals;
a latch located at a first end of the connector base for locking the electronic card inserted into the card slot; and
a releasing member;
wherein the releasing member comprises a lever and a moving member, the lever is connected with the latch at a first end thereof and coupled to the moving member at an opposite second end thereof, the lever further has a spring portion, the spring portion keeps the lever in a preliminary position to keep the latch in an opening state, and the spring portion is able to push the lever to restore the latch back to the opening state when the electronic card is pulled out.

17. The card edge connector as claimed in claim 16, wherein the spring portion extends slantwise from the second end of the lever and presses against a lower portion of the connector base or a printed circuit board where the connector base is mounted.
